(19) United States
(12) Patent Application Publication
(10) Pub. No.: US 2011/0122606 A1
(43) Pub. Date: May 26, 2011

(54) SOLAR ENERGY COLLECTOR AND LAMP USING THE SAME

(75) Inventors: CHIN-LONG KU, Tu-Cheng (TW); LONG HUANG, Shenzhen City (CN)

(73) Assignees: Fu Zhun Precision Industry (Shen Zhen) Co., Ltd., Shenzhen City (CN); Foxconn Technology Co., Ltd., Tu-Cheng (TW)

(21) Appl. No.: 12/763,216

(22) Filed: Apr. 20, 2010

(30) Foreign Application Priority Data
Nov. 20, 2009 (CN) 200910310148.4

(51) Int. Cl. F21L 4/00; H01L 31/042

(52) U.S. Cl. 362/183; 136/246

(57) ABSTRACT

A lamp includes a lamp body, a control module and a solar energy collector. The solar energy collector includes a first motor, a second motor coupled to the first motor, a solar energy absorption board, and a detection apparatus mounted on the solar energy absorption board. The solar energy absorption board coupled to the second rotary rod. The detection apparatus includes two first photosensitive resistors mounted opposite to each other and two second photosensitive resistors mounted opposite to each other. The control module controls the first motor to rotate when a voltage difference between the first photosensitive resistors is detected; the control module controls the second motor to rotate when a voltage difference between the second photosensitive resistors is detected.

### BACKGROUND

1. Technical Field

The present disclosure relates to a solar energy collector and, more particularly, to a solar energy collector which can automatically adjust an angle between solar rays and a solar energy absorption board. The present disclosure further relates a lamp using the solar energy collector.

2. Description of Related Art

There are a number of ways to collect solar energy, one of which is to track the sun during movement across the sky from sunrise to sunset. This technique obviously results in a greater recovery of solar energy during a given day than a stationary approach wherein the solar panel remains in a fixed position. The system must, however, be programmed differently for different locations on the earth's surface, as well as for different days during the year. Such settings tend to be complicated, uneconomical and unreliable.

What is needed, therefore, is a solar energy collector providing efficient and dependable collection of solar energy.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an assembled view of a lamp in accordance with an embodiment of the present disclosure.

FIG. 2 is a top view of a solar energy absorption board of the lamp of FIG. 1.

FIGS. 3-4 are flow charts of solar energy control processes of a solar energy collector of the lamp of FIG. 1.

### DETAILED DESCRIPTION

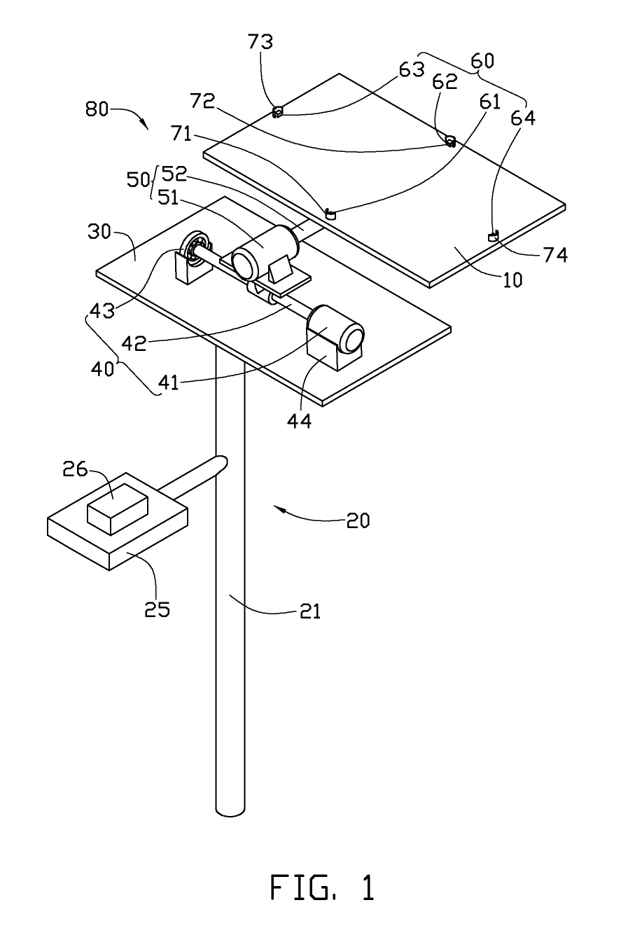

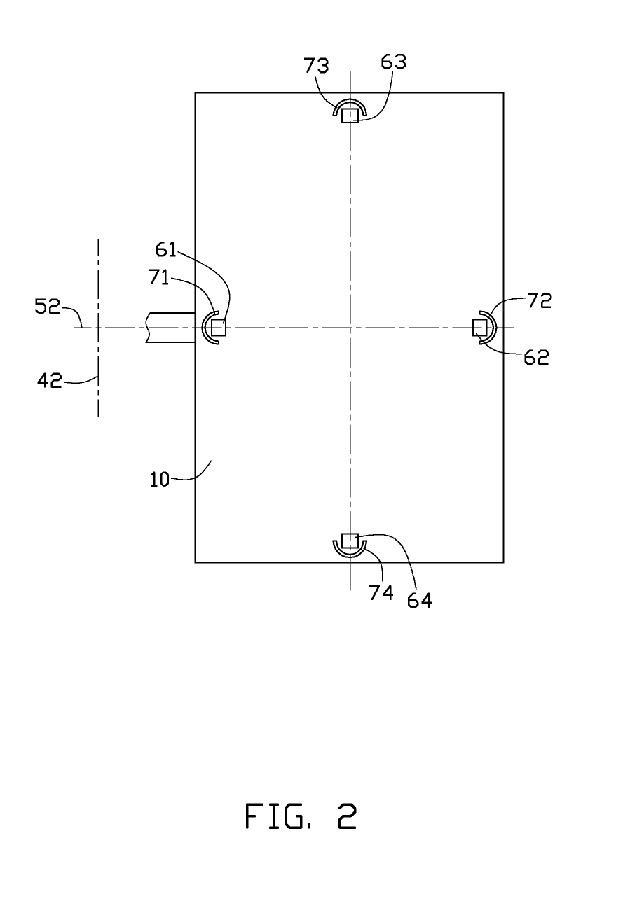

Referring to FIGS. 1-2, a lamp 20 using a solar energy collector 80 in accordance with an embodiment of the disclosure is illustrated. The solar energy collector 80 comprises a location adjuster (not labeled) and a solar energy absorption board 10 mounted on the location adjuster. The location adjuster comprises a base 30 mounted at a top of the lamp 20, a first motor 40 mounted on the base 30, and a second motor 50 coupled to the first motor 40. The solar energy absorption board 10 is coupled to the second motor 50. The location adjuster pivots the solar energy absorption board 10 through a full range of motion. A detection apparatus 60 is mounted on the solar energy absorption board 10.

The lamp 20 includes a lamp post 21 and a lamp body 25 mounted on the lamp post 21. A control circuit 26 is mounted on the lamp body 25 and electrically connects with the lamp body 25, the first motor 40, the second motor 50 and the solar energy absorption board 10.

The first motor 40 includes a main body 41 and a rotary rod 42 coupled to the main body 41. The main body 41 is mounted on the base 30 via a seat 44. In this embodiment, the first motor 40 may be a stepping motor or a servo motor. The first motor 40 further comprises a bearing 43 coupled to a free end of the rotary rod 42. The bearing 43 is fixed on the base 30 thereby to enhance a stability of the first motor 40 during an operation thereof.

The second motor 50 is coupled to and located on the rotary rod 42 of the first motor 40. The second motor 50 includes a main body 51 on the rotary rod 42, and a rotary rod 52 coupled to the main body 51. In this embodiment, the first motor 40 is a stepping motor and the rotary rod 52 is perpendicular to the rotary rod 42 of the first motor 40. The solar energy absorption board 10 is coupled to a free end of the rotary rod 52 of the second motor 50. Therefore, the first motor 40 and the second motor 50 of the location adjuster can drive the solar energy absorption board 10 to pivot through a full range of motion (i.e. from a position where the board 10 faces the sun at the morning horizon to a position where the board 10 faces the sun at the evening horizon) so that the solar energy absorption board 10 can always directly face the sun.

The detection apparatus 60 includes two first photosensitive resistors 61, 62, two second photosensitive resistors 63, 64, and four light shields 71, 72, 73, 74 corresponding to the first and second photosensitive resistors 61, 62, 63, 64, respectively. The first photosensitive resistors 61, 62 are located near middle portions of two opposite sides of the solar energy absorption board 10, and the second photosensitive resistors 63, 64 are located near middle portions of other two opposite sides of the solar energy absorption board 10. The light shields 71, 72, 73, 74 are located at outer sides of the first and second photosensitive resistors 61, 62, 63, 64, respectively. Each of the light shields 71, 72, 73, 74 has a semi-circular cross section and extends upwardly from a top surface of the solar energy absorption board 10. Each of the light shields 71, 72, 73, 74 has an opening facing and partly receiving the corresponding one of the first and second photosensitive resistors 61, 62, 63, 64. A height of each of the light shields 71, 72, 73, 74 is higher than that of the first and second photosensitive resistors 61, 62, 63, 64.

A first line extending through a middle of the first photosensitive resistor 61 and a middle of the light shield 71 is perpendicular to the rotary rod 42 of the first motor 40; a second line extending through a middle of the first photosensitive resistor 62 and a middle of the light shield 72 is also perpendicular to the rotary rod 42. In this embodiment, the light shields 71, 72 are located face to face, and the first line and the second line share a same line perpendicular to the rotary rod 42. A third line extending through a middle of the second photosensitive resistor 63 and a middle of the light shield 73 is perpendicular to the rotary rod 52 of the second motor 50; a fourth line extending through a middle of the second photosensitive resistor 64 and a middle of the light shield 74 is also perpendicular to the rotary rod 52. In this embodiment, the light shields 73, 74 are located face to face, and the third line and the fourth line share a same line perpendicular to the rotary rod 52.

The first photosensitive resistors 61, 62 are connected to the control circuit 26, and each are provided with an electric current of same magnitude therethrough. When works under the sun and the solar energy absorption board 10 does not directly face the sun, the first photosensitive resistors 61, 62 receive different amount of solar rays from the sun because the light shields 71, 72 shield different areas of the first photosensitive resistors 61, 62. Accordingly, the first photosensitive resistors 61, 62 produce different voltages across them, respectively, whereby a voltage difference is generated. The voltage difference is detected by the control circuit 26, which in turn controls the first motor 40 to rotate the rotary rod 42, whereby the second motor 50 is rotated and the solar energy absorption board 10 is also rotated about a first plane. The rotary rod 42 stops rotating when the voltage difference between the first photosensitive resistors 61, 62 disappears, in which the first photosensitive resistors 61, 62 receive the same amount of solar rays from the sun.

Also, when the second photosensitive resistors 63, 64 receive different amount of solar rays via the light shields 73, 74, the second photosensitive resistors 63, 64 produce different voltages across them, respectively. The voltage difference is detected by the control circuit 26, which in turn controls the second motor 50 to rotate the rotary rod 52, whereby the solar energy absorption board 10 is also rotated about a second plane which is perpendicular to the first plane. The rotary rod 52 stops rotating when the voltage difference between the second photosensitive resistors 63, 64 disappears, in which the second photosensitive resistors 63, 64 receive the same amount of solar rays from the sun. Thus, the solar energy absorption board 10 is adjusted by the first and second motor 40, 50 and can always directly face the sun; thereby, the solar energy absorption board 10 has maximal absorption efficiency for absorbing the solar energy.

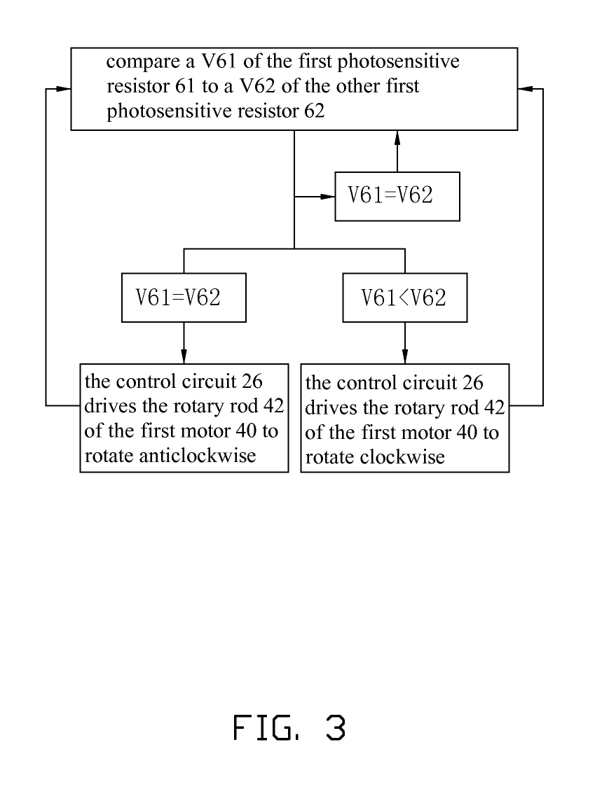

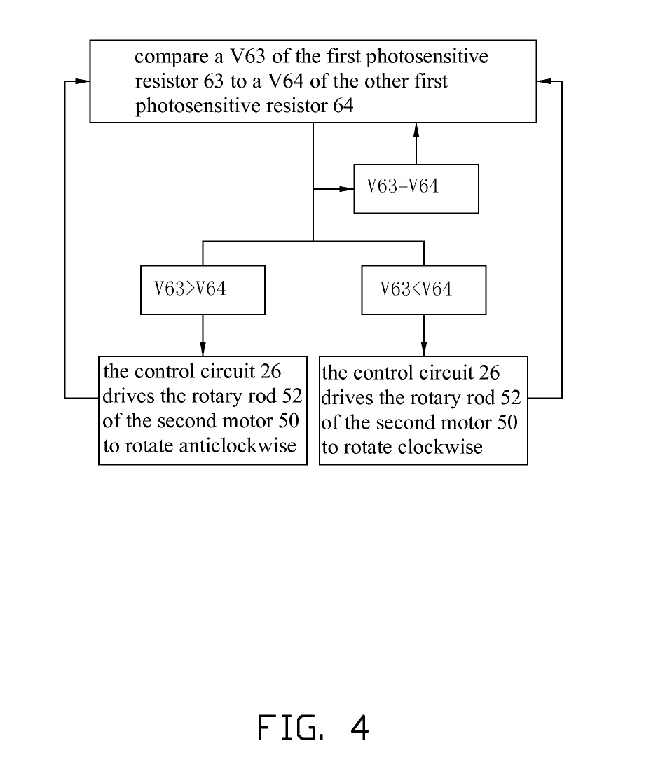

Particularly, if the sun shines slantwise to the solar energy absorption board 10 at a side of the first photosensitive resistor 61, the first photosensitive resistor 61 is located in a shadow of the light shield 71 to receive no solar rays or less solar rays; at the same time, all of the first photosensitive resistor 62 is in the sun and receive solar rays. A resistance of the first photosensitive resistor 62 is smaller than that of the first photosensitive resistor 61, whereby a voltage V61 of the first photosensitive resistor 61 is smaller than a voltage V62 of the first photosensitive resistor 62. If the sun shines slantwise to the solar energy absorption board 10 at a side of the first photosensitive resistor 62, the voltage V61 of the first photosensitive resistor 61 is larger than a voltage V62 of the first photosensitive resistor 62. Referring to FIG. 3, the control circuit 26 detects the voltages V61 and V62 and compares the voltage V61 with the voltage V62; if V61>V62, the control circuit 26 drives the rotary rod 42 to rotate anticlockwise, as viewed from FIG. 1, to enable the solar energy absorption board 10 to rotate around the rotary 42 anticlockwise until the solar energy absorption board 10 is normal to the sun; if V61<V62, the control circuit 26 drives the rotary rod 42 to rotate clockwise whereby the solar energy absorption board 10 is rotated around the rotary rod 42 clockwise until the solar energy absorption board 10 is normal to the sun; if V61=62, the control circuit 26 controls the rotary rod 42 to stop rotating. Referring to FIG. 4, the control circuit 26 detects a voltage V63 of the second photosensitive resistor 63 and a voltage V64 of the second photosensitive resistor 64, and drives the rotary rod 52 to rotate anticlockwise if V63>V64, or rotate clockwise if V63<V64, or stop rotating if V63=V64. Thus, when the sun moves in the sky, the control circuit 26 drives the rotary rod 42 of the first motor 40 and the rotary rod 52 of the first motor 50 to rotate in response to the difference of the voltages V61, V62 and the difference of the voltages V63, V64.

Alternatively, the light shields 71, 72, 73, 74 can be mounted at inner sides of the first and second photosensitive resistors 61, 62, 63, 64. The first photosensitive resistors 61, 62 receives different amounts of the sunrays and the second photosensitive resistors 63, 64 receives different amounts of the sunrays to drive the first and second motors 40, 50 to rotate to adjust an angle between the sun and the solar energy absorption board 10, whereby the solar energy absorption board 10 can always directly face the sun, i.e. being normal to the sun. Through the detection apparatus 60, the lamp can automatically adjust the orientation of the solar energy absorption board 10 so that it can always directly face the sun by following the movement of the sun. Therefore, the solar energy absorption board 10 has maximal absorption efficiency for absorbing the solar energy.

It is to be understood, however, that even though numerous characteristics and advantages of various embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A solar energy collector, comprising:
a solar energy absorption board;
a first motor comprising a first rotary rod;
a second motor coupled to the first rotary rod of the first motor whereby when the first rotary rod rotates the second motor rotates around the first rotary rod, the second motor comprising a second rotary rod, the solar energy absorption board coupled to the second rotary rod, in which when the second motor rotates around the first rotary rod, the solar energy absorption board rotates accordingly, and when the second rotary rod rotates the solar energy absorption board rotates around the second rotary rod;
a detection apparatus mounted on the solar energy absorption board, the detection apparatus comprising two first photosensitive resistors mounted opposite to each other and two second photosensitive resistors mounted opposite to each other; and
a control module connecting with the first motor, the second motor, and the detection apparatus respectively;
wherein the control module controls the first rotary rod of the first motor to rotate when a voltage difference between the first photosensitive resistors is detected by the control module, and the control module controls the second rotary rod of the second motor to rotate when a voltage difference between the second photosensitive resistors is detected by the control module.

2. The solar energy collector as claimed in claim 1, wherein the detection apparatus further comprises four light shields mounted correspondingly at outer sides of the first and second photosensitive resistors, respectively.

3. The solar energy collector as claimed in claim 2, wherein each of the light shields extends upwardly from a top surface of the solar energy absorption board, and face a corresponding one of the first and second photosensitive resistors.

4. The solar energy collector as claimed in claim 3, wherein each of the light shields has a semi-circular cross section and partly receives the corresponding one of the first and second photosensitive resistors.

5. The solar energy collector as claimed in claim 4, wherein a line extending through one of first photosensitive resistors and a middle portion of a corresponding light shield is perpendicular to the first rotary rod of the first motor.

6. The solar energy collector as claimed in claim 4, wherein a line extending through one of second photosensitive resistors and a middle portion of a corresponding light shield is perpendicular to the second rotary rod of the second motor.

7. The solar energy collector as claimed in claim 1, wherein the first rotary rod of the first motor is perpendicular to the second rotary rod of the second motor.

8. The solar energy collector as claimed in claim 2, wherein the first photosensitive resistors are located near middle portions of two opposite sides of the solar energy absorption board, and the second photosensitive resistors are located near middle portions of other two opposite sides of the solar energy absorption board.

9. A lamp, comprising:
a lamp body;
a control module electrically connecting with the lamp body; and
a solar energy collector electrically connecting with the control module, the solar energy collector comprising:
a solar energy absorption board;
a first motor comprising a first rotary rod;
a second motor coupled to the first rotary rod of the first motor, the second motor comprising a second rotary rod, the solar energy absorption board coupled to the second rotary rod, wherein the solar energy absorption boards rotates about a first plane when the first rotary rod rotates and about a second plane when the second rotary rod rotates, the first plane being perpendicular to the second plane; and
a detection apparatus mounted on the solar energy absorption board, the detection apparatus comprising two first photosensitive resistors mounted opposite to each other and two second photosensitive resistors mounted opposite to each other;
wherein the control module controls the first rotary rod of the first motor to rotate when a voltage difference between the first photosensitive resistors is detected by the control module, and the control module controls the second rotary rod of the second motor to rotate when a voltage difference between the second photosensitive resistors is detected by the control module.

10. The lamp as claimed in claim 9, wherein the detection apparatus further comprises four light shields mounted correspondingly at outer sides of the first and second photosensitive resistors, respectively.

11. The lamp as claimed in claim 10, wherein each of the light shields extends upwardly from a top surface of the solar energy absorption board, and face a corresponding one of the first and second photosensitive resistors.

12. The lamp as claimed in claim 11, wherein each of the light shields has a semi-circular cross section and partly receives the corresponding one of the first and second photosensitive resistors.

13. The lamp as claimed in claim 12, wherein a line extending through one of first photosensitive resistors and a middle portion of a corresponding light shield is perpendicular to the first rotary rod of the first motor.

14. The lamp as claimed in claim 12, wherein a line extending through one of second photosensitive resistors and a middle portion of a corresponding light shield is perpendicular to the second rotary rod of the second motor.

15. The lamp as claimed in claim 9, wherein the first rotary rod of the first motor is perpendicular to the second rotary rod of the second motor.
